(19) United States
(12) Patent Application Publication
(10) Pub. No.: US 2012/0175245 A1
(43) Pub. Date: Jul. 12, 2012

(54) GAP FILL IMPROVEMENT METHODS FOR PHASE-CHANGE MATERIALS

(76) Inventors: Mengqi Ye, Milpitas, CA (US); Hua Chung, San Jacinto, CA (US); Goichi Yoshidome, Emeryville, CA (US); Philip Fulmer, Santa Clara, CA (US)

(21) Appl. No.: 13/422,671

(22) Filed: Mar. 16, 2012

Related U.S. Application Data
(63) Continuation of application No. 12/255,864, filed on Oct. 22, 2008.

(51) Int. Cl. C23C 14/34

(52) U.S. Cl. 204/192.15

(57) ABSTRACT

Methods and apparatus are provided for depositing phase-change materials. In one embodiment, a method is provided for processing a substrate including positioning a substrate in a processing chamber having a phase change material-based target coupled to a first power source, one or more coils coupled to a second power source, a substrate support coupled to a third power source, providing a processing gas to the processing chamber, biasing the phase change material-based target with continuous DC or pulsed DC power, applying power to the coils to generate an inductively coupled plasma, applying a bias to the substrate support, sputtering material from the target, ionizing the sputtered materials, and depositing the sputtered materials on the substrate surface.

### CROSS-REFERENCE TO RELATED APPLICATIONS

This application is a continuation application of co-pending U.S. patent application Ser. No. 12/255,864 (Attorney Docket No. 13592), filed on Oct. 22, 2008, which is herein incorporated by reference.

### BACKGROUND OF THE INVENTION

1. Field of the Invention

Embodiments of the present invention generally relate to a sputtering process for deposition of materials on a substrate surface.

2. Description of the Related Art

In the fabrication of circuits and displays, new materials and processes are constantly being developed to fabricate ever smaller active and passive features. For example, phase change memory materials can be used to form features having sizes of 45 nanometers or smaller for dynamic random access memory (DRAM) applications. Chalcogenides are a type of phase-changeable materials which undergo a phase transformation from a polycrystalline to an amorphous phase when activated by energy in the form of heat, electrons or photons.

Chalcogenide materials are often deposited by sputtering processes in which a sputtering target in a sputtering chamber is energetically bombarded by plasma species causing material to be knocked off the target and deposited onto a substrate. Typically, the sputtering chamber comprises an enclosure around a sputtering target facing a substrate support, a process zone into which a process gas is introduced, a gas energizer to energize the process gas to form the plasma, and an exhaust port to exhaust and control the pressure of the process gas in the chamber. The sputtering target includes a chalcogenide material to deposit chalcogenide on the substrate.

However filling of high aspect ratio (>1) microstructures with sputtering is very challenging. In addition to the inherent limits of sputtering, chalcogenide-based materials have low thermal conductivity, which makes it impractical to improve gap fill by increasing sputtering power to increase ionization ratio, since higher power density on the target surface tends to overheat and weaken sputtering targets, generate large number of defects, and lower the yields. Chemical vapor deposition and atomic layer deposition are being developed to improve gap fill. However, both methods are more costly, and require extensive development on precursors before they can be used for high volume production.

Thus it is desirable to have a sputtering target and process for depositing chalcogenide material on a substrate with low defect counts. It is further desirable to be able to deposit the sputtered film with reproducible and consistent results.

### SUMMARY OF THE INVENTION

The present invention generally for the deposition of phase-change materials. In one embodiment, a method is provided for processing a substrate including positioning a substrate in a processing chamber having a phase change material-based target coupled to a first power source, one or more coils coupled to a second power source, a substrate support coupled to a third power source, providing a processing gas to the processing chamber, biasing the phase change material-based target with continuous DC or pulsed DC power, applying power to the coils to generate an inductively coupled plasma, applying a bias to the substrate support, sputtering material from the target, ionizing the sputtered materials, and depositing the sputtered materials on the substrate surface.

In another embodiment, a method is provided for processing a substrate including positioning a substrate in a processing chamber having a chalcogenide-based target coupled to a first power source, one or more coils coupled to a second power source, providing a processing gas to the processing chamber, biasing the target with RF power, applying RF power to the coils to generate an inductively coupled plasma, sputtering material from the target, ionizing the sputtered materials, and depositing the sputtered materials on the substrate surface.

In another embodiment, a method is provided for processing a substrate including positioning a substrate in a processing chamber having a chalcogenide-based target coupled to a first power source, a substrate support coupled to a second power source, providing a processing gas to the processing chamber, biasing the target with continuous DC, pulsed DC power, or RF power, applying a single or dual frequency RF power to the substrate support, sputtering material from the target, ionizing the sputtered materials, and depositing the sputtered materials on the substrate surface.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of one embodiment of a sputter chamber for use with the processes described herein; and

FIG. 2 is a schematic cross-section view of one embodiment of a phase-change memory cell; and

FIGS. 3A and 3B illustrate schematic cross-section views of additional embodiments of phase-change memory cells.

### DETAILED DESCRIPTION

The present invention generally provides for the deposition of phase-change materials. In one embodiment, the phase-change materials are deposited by a chalcogenide-based target coupled to a first power source, one or more coils coupled to a second power source, and a substrate support coupled to a third power source. The target is then biased with continuous DC or pulsed DC power while applying power to the coils to generate an inductively coupled plasma and applying a bias to the substrate support. Material is then sputtered from the target, and alternatively, the coils, and with the coils ionizing the sputtered materials to deposit the sputtered materials on the substrate surface and in aspect ratio features having a ratio of 1:1 or greater. Alternatively, RF power may be applied to the target.

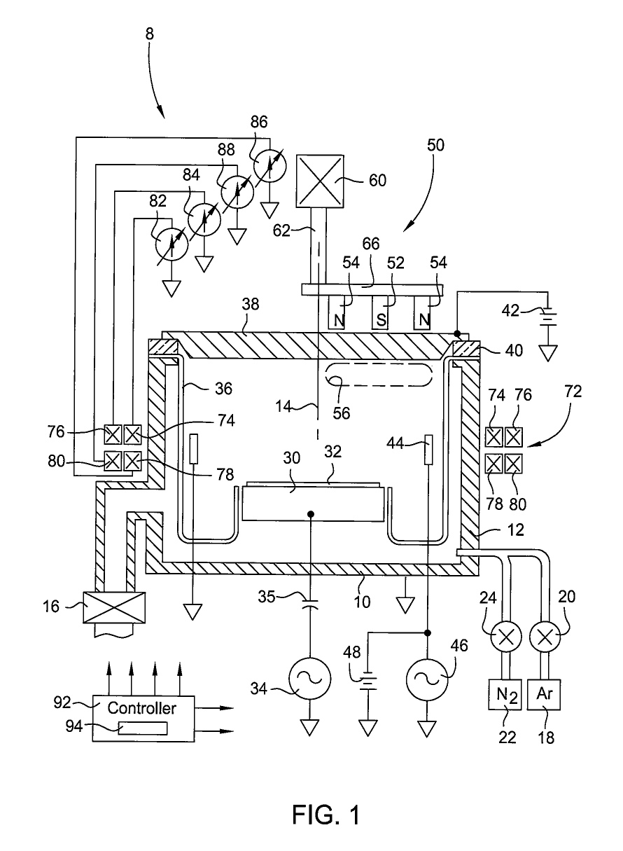

FIG. 1 is a schematic cross-sectional view of one embodiment of a sputter chamber for use with the processes described herein. A magnetron sputter reactor 8, illustrated schematically in cross section in FIG. 1, can effectively sputter thin films of target material into holes having high aspect ratios and can further act to plasma clean the substrate and selectively etch portions of the deposited target material-based films. The reactor 8 includes a vacuum chamber 10 including sidewalls 12 arranged generally symmetrically about a central axis 14. A vacuum pump system 16 pumps the vacuum chamber 10 to a very low base pressure in the range of less than 1 Torr. A gas source 18 connected to the chamber through a mass flow controller 20 supplies a processing gas, such as argon, into the vacuum chamber 10 for the sputtering process. A second gas source 22 may supply dopants, such as nitrogen gas, into the chamber through another mass flow controller 24 when a doped target material is being deposited.

A substrate support 30 arranged about the central axis 14 holds a substrate 32 or other substrate to be sputter coated. An non-illustrated clamp ring or electrostatic chuck may be used to hold the substrate 32 to the substrate support 30. An RF power source 34 supplying electrical power (referred to as RF bias supply or power) preferably in the low megahertz range is connected through a capacitive coupling circuit 35 to the substrate support 30, which is conductive and acts as an electrode. In the presence of a plasma, the RF biased substrate support 30 develops a negative DC bias, which is effective at attracting and accelerating positive ions in the plasma. Alternatively, the substrate support may be coupled to a DC power source. An electrically grounded shield 36 protects the chamber walls and the sides of the substrate support 30 from sputter deposition. Other shield configurations are possible. The substrate support 30 may comprise an electrostatic chuck. The power source 34 may be the same or an individual power source as coupled to the coils and/or target.

A target 38 is arranged in opposition to the substrate support 30 and is vacuum sealed to the chamber 10 through an isolator 40. At least the front surface of the target 38 is composed of a metallic material to be deposited on the substrate 32, which in this embodiment is a phase change material. A target power source, such as a DC power source, 42 electrically biases the target 38 to a negative voltage with respect to the grounded shield 36 to cause the processing gas to discharge into a plasma such that the positively charged argon ions are attracted to the negatively biased target 38 and sputter target material. Some of the sputtered target material deposits on the substrate 32 to form a layer of the target material. In reactive sputtering, nitrogen gas is additionally admitted from the gas source 18, such as nitrogen, into the chamber 10 to react with the target material being sputtered to cause the deposition of a nitride layer on the substrate 32. The DC power source 42 may be substituted with an RF power source as described with the coils herein. The power source 42 may be the same or an individual power source as coupled to the coils and/or substrate support.

The reactor 8 additionally includes an inductive coil 44, preferably having one wide turn wrapped around the central axis 14 just inside of the grounded shield 36 and positioned above the substrate support 30 approximately one-third of the distance to the target 38. The coil 44 is supported on the grounded shield 36 or another inner tubular shield but electrically isolated from it, and an electrical lead penetrates the sidewalls of the shield 36 and chamber 10 to power the RF coil 44. Preferably, the coil 44 is composed of the same material as the target 38. An RF power source 46 applies RF current to the coil 44 to induce an axial RF magnetic field within the chamber and hence generate an azimuthal RF electric field that is very effective at coupling power into the plasma and increasing its density. The RF power inductively coupled into the vacuum chamber 10 through the RF coil 44 may be used as the primary plasma power source when the target power is turned off and the sputter reactor is being used to etch the substrate 32 with argon ions or for other purposes. The inductively coupled RF power may alternatively act to increase the density of the plasma primarily generated by the powered target 38 and extending towards the substrate support 30.

The coil 44 may be composed of the target material, for example, the phase change materials as described herein, to act as a secondary sputtering target under the proper conditions. Additionally, the coils may be of one or more elements of phase-change-based materials and materials that can form alloys with the phase change materials. The coils may be comprised of dopants of the phase change-based materials including titanium, tantalum, tin, indium, bismuth, silicon, aluminum, copper, and combinations thereof, or desired dopants in phase change materials, such as bismuth, tin, indium, silicon, oxides, nitrides, or combinations thereof. The RF coil may comprise one or more coils, such as between 1 and 5 coils, either individual coils or part of the same coil encircling the chamber one or more windings.

A DC power source 48 may also be connected to the RF coil 44 to apply a DC voltage to the RF coil 44. The illustrated parallel connection of the coil RF supply 46 and the coil DC supply 48 is functional only. They may be connected in series. Alternatively, they may be connected in parallel with respective coupling and filtering circuits to allow selective imposition of both RF and DC power, for example a capacitive circuit in series with the RF power source 46 and an inductive circuit in series with the DC power source 48. A single coil power source can be designed for both types of power.

The target sputtering rate and sputter ionization fraction of the sputtered atoms can be greatly increased by placing a magnetron 50 is back of the target 38. The magnetron 50 preferably is small, strong, and unbalanced. The smallness and strength increase the ionization fraction and the imbalance causes a magnetic field to project into the processing region towards the substrate support 30. Such a magnetron includes an inner pole 52 of one magnetic polarity along the central axis and an outer pole 54 which surrounds the inner pole 52 and has the opposite magnetic polarity. The magnetic field extending between the poles 52, 54 in front of the target 38 creates a high-density plasma region 56 adjacent the front face of the target 38, which greatly increases the sputtering rate. The magnetron 50 is unbalanced in the sense that the total magnetic intensity of the outer pole 54, that is, the magnetic flux integrated over its area, is substantially greater than that of the inner pole, for example, by a factor of two or more. The unbalanced magnetic field projects from the target 38 toward the substrate 32 to extend the plasma and to guide sputtered ions to the substrate 32 and reduce plasma diffusion to the sides.

To provide a more uniform target sputtering pattern, the magnetron 50 is typically formed in a triangular or a closed and generally azimuthally arced shape that is asymmetrical about the central axis 14. However, a motor 60 drives a rotary shaft 62 extending along the central axis 14 and fixed to a plate 66 supporting the magnetic poles 52, 54 to rotate the magnetron 50 about the central axis 14 and produce an azimuthally uniform time-averaged magnetic field. The arc-shaped magnetron disposed closer to the target periphery is often used if sputtering from the edge of the target is to be emphasized. If the magnetic poles 52, 54 are formed by respective arrays of opposed cylindrical permanent magnets, the plate 66 is advantageously formed of a magnetic material such as magnetically soft stainless steel to serve as a magnetic yoke magnetically coupling the backs of the two poles 52, 54. Magnetron systems are known in which the radial position of the magnetron, especially an arc-shaped one, can be varied between different phases of the sputtering process and chamber cleaning as described by Gung et al. in U.S. patent application Ser. No. 10/949,735, filed Sep. 23, 2004 and published as U.S. Application Publication 2005/0211548 and by Miller et al. in U.S. patent application Ser. No. 11/226,858, filed Sep. 14, 2005, both incorporated herein by reference in their entireties.

Great flexibility is afforded by a quadruple electromagnet array 72 positioned generally in back of the RF coil 44. The quadruple electromagnet array 72 includes four solenoidal coils 74, 76, 78, 80 wrapped generally circularly symmetrically about the central axis 14 of the reactor 70. The coils 74, 76, 78, 80 are preferably arranged in a two-dimensional array annularly extending around the central axis. The nomenclature is adopted of the top inner magnet (TIM) 74, top outer magnet (TOM) 76, bottom inner magnet (BIM) 78, and bottom outer magnet (BOM) 80. The coils 74, 76, 78, 80 may each be separately powered, for example, by respective variable DC current supplies 82, 84, 86, 88, preferably bipolar DC supplies. Corresponding non-illustrated grounds or return paths are connected to the other ends of the multi-wrap coils 74, 76, 78, 80. However, in the most general case, not all coils 74, 76, 78, 80 need be connected to a common ground or other common potential. Other wiring patterns are possible.

All coils 74, 76, 78, 80 have at least one and preferably two end connections that are readily accessible on the exterior of the assembled chamber to allow connection to separate power supplies or other current paths and to allow easy reconfiguration of these connections, thereby greatly increasing the flexibility of configuring the chamber during development or for different applications. In production, it is possible that the number of current supplies 82, 84, 86, 88 may be reduced but the capability remains to selectively and separately power the four different coils 74, 76, 78, 80, preferably with selected polarities, if the need arises as the process changes for the sputter reactor 8. The number of coils may be varied as necessary for performing the processes herein. The magnetic coils 74, 76, 78, 80 may be formed of permanent magnet pole pieces.

In one embodiment of the chamber, one or more magnetic coils as described may be disposed in the chamber. Examples, of such a chamber design are the EnCoRe™ processing chamber, the EnCoRe™ II processing chamber and the SIP (Self-Ionized Plasma) EnCoRe II Ta(N) processing chamber, each of which is commercially available from Applied Materials of Santa Clara, Calif.

The eight wires of the four coils 74, 76, 78, 80 may be connected directly or through a connection board to one or more power supplies 82, 84, 86, 88. An operator can manually reconfigure the connection scheme with jumper cables between selected pairs of terminals without disassembling either the coil array 72 or the vacuum chamber 10. It is possible also to use, electronically controlled switches for the different configurations. During operational use once a process recipe has been established, the number of active coils and power supplies may be reduced. Further, current splitters and combiners and serial (parallel and anti-parallel) connections of coils can be used once the general process regime has been established.

A controller 92 contains a memory 94, which may be a removable recorded magnetic or optical disk, memory stick, or other similar memory means, which is loaded with a single- or multi-step process recipe for achieving a desired structure in the substrate 32. The controller 92 accordingly controls the process control elements, for example, the vacuum pump system 16, the process gas mass flow controllers 20, 24, the substrate bias supply 34, the target power source 42, the RF and DC coil supplies 48, 49, the magnetron motor 60 to control its rotation rate and hence the position of the magnetron, and the four electromagnet current supplies 82, 84, 86, 88.

In an alternative embodiment of the processing chamber, ionization of the plasma particles may be achieved by capacitively charged plates disposed in the processing chamber.

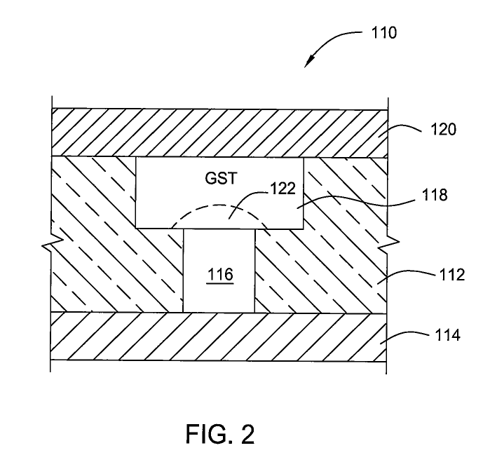

FIG. 2 is a schematic cross-section view of one embodiment of a phase-change memory cell. One example of a phase-change memory cell 110 is illustrated although the invention is not limited to such a structure. A dielectric layer 112, for example, of silicon oxide, is grown over a bottom electrode 114. A vertical structure is etched through the dielectric layer 112. A via 116 in the lower portion is filled with a metal to contact the bottom electrode 114. A wider GST plug 118 at the top of the dielectric layer 116, and contacting and overhanging the via 116, is filled with a phase-change material, such as the metal chalcogenide germanium antimony telluride (GST). A top electrode is 120 is deposited over the GST plug 118.

In operation, a short electrical pulse is applied through the electrodes 114, 120 to the GST plug 118 to cause a phase-change region 122 to melt. The remainder of the GST plug 118 is preferably always in the conductive crystalline state. Depending on whether the melting pulse is short or long, the phase-change region 122 either quickly cools and quenches to a high-resistance amorphous state or slowly cools to a low-resistance crystalline state. The state of the phase-change memory cell 110 can be read by measuring its resistance between the electrodes 114, 120 across the GST plug.

Phase-change memory materials (PCM) may be disposed to improve gap fill of high aspect ratio vias (height to width ratios of greater than 1:1) and trenches by using a separate ionization source to ionize sputtered materials.

One example of PCM materials used as the target materials are chalcogenides. Chalcogenides are materials that exhibit phase transition and include a combination of elements from Groups 11-16 of the IUPAC Periodic Table (also known respectively as Groups IB, IIB, IIIA, IVA, VA, and VIA). Suitable examples of element combinations include AgSe, GeSb, GeSe, GeTe, SbTe, GeSbTe, GeSeTe, AgInSbTe, GeSbSeTe, TeGeSbS, other materials such as doped GeSb, and as well as other combinations. The chalcogenide material can be a solid solution without a fixed stoichiometric ratio, or can have a definite stoichiometric ratio. In one version, the chalcogenide material comprises GeSbTe in a ratio of 2:2:5 (Ge₂Sb₂Te₅) or in another example, Sb₂Te₃. Other materials which can be added to the chalcogenide materials, such as GeSbTe chalcogenide, include nitrogen (N), bismuth (Bi), tin (Sn), indium (In), silicon (Si) or combinations thereof. Examples of targets made from chalcogenide materials are disclosed in co-pending U.S. patent application Ser. No. 11/927,605, filed on Oct. 29, 2007, which is incorporated by reference herein to the extent not inconsistent with the claim aspects and description herein.

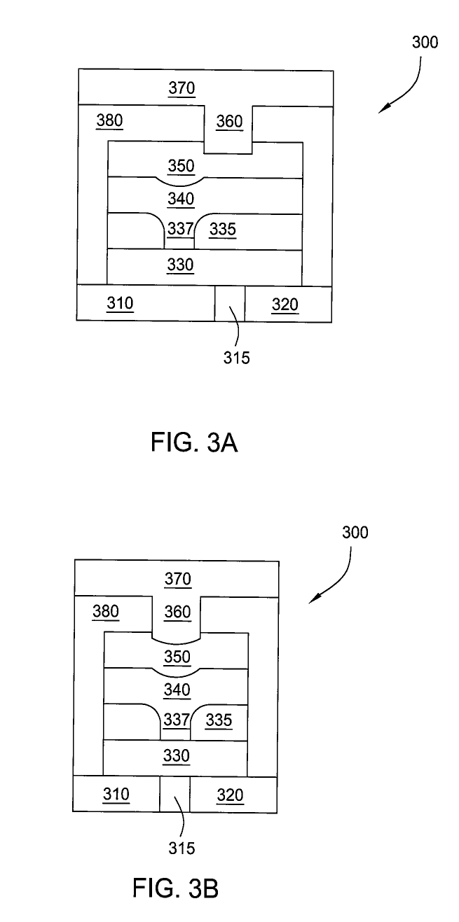

FIGS. 3A and 3B illustrate schematic cross-section views of additional embodiments of phase-change memory cells. FIG. 3A is one example of a off-axis confined cell structure of PRAM having the phase-change material formed therein. The structure 300 may be formed over a device, such as CMOS transistor. An interlayer dielectric material 310 is formed. A bottom electrode contact 320 is formed in the interlayer dielectric material 310 to define a CMOS transistor contact 315. A bottom electrode 330 is formed contacting the bottom electrode contact 320. A dielectric material 335 is deposited on the bottom electrode 330, and the dielectric material 335 is then etched or patterned to form a pore 337 exposing the bottom electrode 330. A layer of a phase-change material 340, such as the metal chalcogenide germanium antimony telluride (GST), is formed on the dielectric material 335 and in the pore 337. A top electrode 350 is formed on the phase-change material 340. The structure may then be patterned and a second interlayer dielectric material 380 is deposited around the layers 330, 340, and 350. A top electrode contact 360 in electrical communication with the top electrode is formed in the second dielectric layer 380, and the top electrode contact 360 may be part of a first metal line 370 in a semiconductor leveling scheme. The pore 337 is off-axis from the top electrode contact 360 and the CMOS transistor contact 315, which the top electrode contact 360 and the CMOS transistor contact 315 may be on-axis with one another.

FIG. 3B is formed in the same manner of as the structure 300 of FIG. 3A, with the distinction that the pore 337, the top electrode contact 360, and the CMOS transistor contact 315, are on-axis with one another.

It is believed that using a secondary ionization source, separate from either continuous DC or pulsed DC power input to sputtering targets, can decouple the sputtering and ionization processes, and has the capability of achieving high ionization ratios without using high sputtering power (which will overheat targets and cause defect issue), therefore achieving good gap fill and good defect performance simultaneously.

In one embodiment of a process for depositing a PCM material, the process includes providing a substrate to a process chamber having a target with a PCM material as described herein, providing a processing gas to the processing chamber, applying a DC bias or a pulsed DC bias to the target, applying a RF frequency power to the coil, applying a RF bias to the substrate support, maintaining a chamber pressure, and maintaining a substrate temperature. Under such a process, the power application provides for sputtering material from the target, ionizing the sputtered materials, and depositing the sputtered materials on the substrate surface and in the aspect ratio features.

The DC power source coupled to the target ignites and maintains the plasma of the processing gas. The processing gas is energized to ignite a plasma producing positive ions, such as positive argon ions, that are accelerated to the target and sputter the target material. A DC power source may apply a bias to the target includes providing a power level from about 50 Watts (W) to about 10,000 Watts, such as from about 50 W to about 5000 W, for example about 500 W. The DC power source may also be a pulsed DC power source that applies a predetermined pulse waveform to the target to ignite and maintain the plasma which provides for sputtering and etching phases of the waveform.

In the pulsed process, the sputter deposition process occurs over a time period during which the target is held at a negative DC potential, for example, from about −200 V to about −1000 V DC, and etching or reconditioning of the target occurs when the target is held at a positive potential for a period of time, for example, from about 25 V to about 50V DC and may be in a range of 5 to 25% of negative voltage DC potential. The pulsed DC power may be applied from about 50 Watts (W) to about 10,000 Watts, such as from about 50 W to about 5000 W, for example about 500 W. The pulsed waveform repeats on a repetition period corresponding to a frequency from about 10 kHz to about 300 kHz, for example about 25 kHz, and which may be modulated at a frequency of less than about 10 kHz, such as from 1 kHz to 5 KHz. The power waveform pulses many times for each rotation of the magnetron.

In one example of a pulsed DC bias power application, an average DC power input to the target is modulated in such a way as to provide 100 W for 95 milliseconds (ms), and 20000 W for 5 ms, 100 W for another 95 ms, for an average DC power of (100*95+20000*5)/100=1095 W. On top of the modulation, the DC waveform is pulsed at 25 kHz with 2.5 microseconds (μs) reverse time. It is believed that the modulated DC bias achieves both high peak power for high ionization of the plasma gas, and a low average power to prevent overheating of the target.

A RF power source applies RF current to the coil to induce an axial RF magnetic field within the chamber and hence generate an azimuthal RF electric field that effectively couples power into the plasma and increases the plasma density. The power application to the coil may result in the coil acting as a secondary target. The RF power source applies from about 100 W to about 10,000 W, such as from about 100 W to about 6000 W, for example about 2,000 W, to each of the one or more coils. For the deposition process, the RF power may be applied at a higher power level than the DC power application, for example a RF power level to DC power level ratio of 2:1 or greater, such as from about 2:1 to about 6:1, for example, about 4:1, may be used. The frequency provided by the RF power source may be in a range from about 10 MHz to about 30 MHz, for example, about 13.56 MHz.

Alternatively, a dual-frequency source of mixed RF power provides a high frequency power in a range from about 10 MHz to about 30 MHz, for example, about 13.56 MHz, as well as a low frequency power in a range of from about 10 KHz to about 1 MHz, for example, about 350 KHz, with the ratio of the second frequency RF power to the total mixed frequency power is preferably less than about 0.6 to 1.0 (0.6:1). Alternatively, a dual-frequency source of mixed RF power provides two high frequency powers in a range from about 10 MHz to about 100 MHz, for example, about 13.56 MHz and 60 MHz.

A third power source, such as a RF power source, or alternatively, a DC power source, may apply a power level from about 0 W to about 1,000 W, such as from about 100 W to about 1000 W, for example about 300 W to the substrate support to accelerate ionized sputter atoms in the plasma to a substrate disposed thereon.

A processing gas used to sputter the target may be an inert gas, such as a noble gas, for example, helium, argon, xenon, neon, or combinations thereof, of which argon is most preferred. The processing gas may be introduced into the chamber at a flow rate from about 5 sccm to about 220 sccm, for example, about 60 sccm. The processing gas may also include dopants, such as nitrogen and other known dopant materials for phase-change materials, for the deposited materials. For example, the PCM material may be nitrogen doped up to about 10 atomic %, such as from about 2 to about 5 atomic %, by which a dopant gas, such as nitrogen gas, is selectively supplied during plasma sputtering of the target. A dopant gas may be introduced into the chamber at a flow rate from about 0.05 sccm to about 40 sccm, such as from about 0.1 sccm to about 20 sccm, for example, about 2 sccm.

The sputtering process may be performed by maintaining a chamber pressure of about 5 milliTorr or greater, such as from about 6 milliTorr to about 80 milliTorr, for example, about 26 milliTorr. The substrate and target may be spaced from about 50 mm to about 500 mm, such as from about 100 mm to about 400 mm, for example, about 290 mm, apart.

The sputtering process may be performed by maintaining a substrate temperature from about 25° C. to about 350° C., such as at a temperature from about 25° C. to about 300° C., for example, about 30° C. or 200° C. The sputtering temperature may be selected to provide for deposition of the phase-change material in different crystalline phases. An amorphous phase deposition may occur at a deposition temperature of about 30° C. and a polycrystalline phase deposition may occur at 200° C. Different phase change materials, and different atomic structures of the same phase change materials will have different temperature ranges for deposition amorphous and polycrystalline materials. For example, for a GST material, such as GeSbTe (Ge₂Sb₂Te₅), may be considered to have amorphous deposition at about 105° C. or less and a polycrystalline deposition at temperature above 105° C. The temperature description of amorphous and polycrystalline depositions herein may be applied to all embodiments of the sputtering process described herein.

An example of the deposition process comprises utilizing a target of Ge₂Sb₂Te₅ material, introducing an argon processing gas at a flow rate of about 58 sccm, applying a DC power level of about 500 W to the target, applying a RF power level of about 2000 W to one or more coils, applying a bias to the substrate of about 300 W, maintaining a chamber pressure of about 26 milliTorr, maintaining a chamber temperature of about 30° C., at a target to substrate spacing of about 290 mm.

In another embodiment of a process for depositing a PCM material, the process includes providing a substrate to a process chamber having a target with a PCM material as described herein, providing a processing gas to the processing chamber, applying a RF frequency power to the target, applying a RF frequency power to the coil, and applying an optional RF power bias to the substrate support. Under such a process, the power application provides for sputtering material from the target, ionizing the sputtered materials, and depositing the sputtered materials on the substrate surface and in the aspect ratio features.

A RF power source applies RF power to the target. The RF power source applies from about 100 W to about 10,000 W, such as from about 500 W to about 5000 W, for example about 1000 W. The frequency provided by the RF power source may be in a range from about 10 MHz to about 100 MHz, for example, about 13.56 MHz or 60 MHz. Alternatively, a dual-frequency source of mixed RF power provides a high frequency power in a range from about 2 MHz to about 60 MHz, for example, about 13.56 MHz, as well as a low frequency power in a range of from about 10 KHz to about 2 MHz, for example, about 350 KHz or 60 KHz, with the ratio of the second frequency RF power to the total mixed frequency power is preferably less than about 0.6 to 1.0 (0.6:1). Alternatively, a dual-frequency source of mixed RF power provides two high frequency powers in a range from about 10 MHz to about 100 MHz, for example, about 13.56 MHz and 60 MHz.

A RF power source applies RF current to the coil to induce an axial RF magnetic field within the chamber and hence generate an azimuthal RF electric field that effectively couples power into the plasma and increases the plasma density. The power application to the coil may result in the coil acting as a secondary target. The RF power source applies from about 100 W to about 10,000 W, such as from about 500 W to about 5000 W, for example about 2000 W, to each of the one or more coils. The frequency provided by the RF power source may be in a range from about 10 MHz to about 30 MHz, for example, about 13.56 MHz.

Alternatively, a dual-frequency source of mixed RF power provides a high frequency power in a range from about 2 MHz to about 60 MHz, for example, about 13.56 MHz, as well as a low frequency power in a range of from about 10 KHz to about 1 MHz, for example, about 350 KHz or about 60 KHz, with the ratio of the second RF power to the total mixed frequency power is preferably less than about 0.6 to 1.0 (0.6:1). Alternatively, a dual-frequency source of mixed RF power provides two high frequency powers in a range from about 2 MHz to about 100 MHz, for example, about 13.56 MHz and 60 MHz.

An optional third power source, such as a RF power source, or alternatively, a DC power source, may apply a power level from about 0 W to about 1,000 W, such as from about 100 W to about 500 W, for example about 300 W, to the substrate support to accelerate ionized sputter atoms in the plasma to a substrate disposed thereon.

A processing gas used to sputter the target may be an inert gas, such as a noble gas, for example, helium, xenon, argon, or neon, of which argon is most preferred. The processing gas may be introduced into the chamber at a flow rate from about 5 sccm to about 220 sccm, for example, about 60 sccm. The processing gas may also include dopants, such as nitrogen and other known dopant materials for phase-change materials, for the deposited materials. For example, the PCM material may be nitrogen doped up to about 10 atomic %, such as from about 2 to about 5 atomic %, by which a dopant gas, such as nitrogen gas, is selectively supplied during plasma sputtering of the target. A dopant gas may be introduced into the chamber at a flow rate from about 0.05 sccm to about 40 sccm, such as from about 0.1 sccm to about 20 sccm, for example, about 2 sccm.

The sputtering process may be performed by maintaining a chamber pressure of about 5 milliTorr or greater, such as from about 6 milliTorr to about 100 milliTorr, for example, about 70 milliTorr. The sputtering process may be performed by maintaining a substrate temperature from about 25° C. to about 350° C., such as at a temperature from about 25° C. to about 300° C., for example, about 30° C. or 200° C. The substrate and target may be spaced from about 50 mm to about 500 mm, such as from about 100 mm to about 400 mm, for example, about 190 mm, apart.

An example of the deposition process comprises utilizing a target of Ge₂Sb₂Te₅ material, introducing an argon processing gas at a flow rate of about 140 sccm, applying a RF power level of about 2000 W to the target, applying a RF power level of about 500 W to one or more coils, maintaining a chamber pressure of about 70 milliTorr, maintaining a chamber temperature of about 50° C., at a target to substrate spacing of about 190 mm.

In another embodiment of a process for depositing a PCM material, the process includes providing a substrate to a process chamber having a target with a PCM material as described herein, providing a processing gas to the processing chamber, applying a DC bias, a pulsed DC bias, or RF power to the target, applying a RF frequency power to an electrostatic chuck, maintaining a chamber pressure, and maintaining a substrate temperature. Under such a process, the power application provides for sputtering material from the target, ionizing the sputtered materials, and depositing the sputtered materials on the substrate surface and in the aspect ratio features.

The DC and/or RF power source coupled to the target ignites and maintains the plasma of the processing gas. The processing gas is energized to ignite a plasma producing positive ions, such as positive argon ions, that are accelerated to the target and sputter the target material.

A DC power source may apply a bias to the target includes providing a power level from about 100 Watts (W) to about 10,000 Watts, such as from about 500 W to about 5000 W, for example about 500 W. The DC power source may also be a pulsed DC power source that applies a predetermined pulse waveform to the target to ignite and maintain the plasma which provides for sputtering and etching phases of the waveform. In the pulsed process, the sputter deposition process occurs over a time period during which the target is held at a negative DC potential, for example, from about −200 V to about −1000 V DC, and etching or reconditioning of the target occurs when the target is held at a positive potential for a period of time, for example, from about 25 V to about 50V DC and may be in a range of 5 to 25% of negative voltage DC potential. The pulsed DC power may be applied from about 100 Watts (W) to about 10,000 Watts, such as from about 500 W to about 5000 W, for example about 500 W. The pulsed waveform repeats on a repetition period corresponding to a frequency from about 5 kHz, to about 350 kHz, for example about 25 kHz. The power waveform pulses many times for each rotation of the magnetron.

A RF power source applies RF power to the a substrate support, for example, an electrostatic check. The RF power application may be optional, i.e., an application of 0 W. The RF power source applies from about 1 W to about 5,000 W, such as from about 100 W to about 3000 W, for example about 500 W. The frequency provided by the RF power source may be in a range from about 10 MHz to about 100 MHz, for example, about 13.56 MHz or 60 MHz.

Alternatively, a dual-frequency source of mixed RF power provides a high frequency power in a range from about 10 MHz to about 30 MHz, for example, about 13.56 MHz, as well as a low frequency power in a range of from about 10 KHz to about 1 MHz, for example, about 350 KHz or 60 KHz, with the ratio of the second frequency RF power to the total mixed frequency power is preferably less than about 0.6 to 1.0 (0.6:1). Alternatively, a dual-frequency source of mixed RF power provides two high frequency powers in a range from about 10 MHz to about 100 MHz, for example, about 13.56 MHz and 60 MHz.

A processing gas used to sputter the target may be an inert gas, such as a noble gas, for example, helium, argon, xenon, or neon, of which argon is most preferred. The processing gas may be introduced into the chamber at a flow rate from about 5 sccm to about 220 sccm, for example, about 60 sccm. The processing gas may also include dopants, such as nitrogen and other known dopant materials for phase-change materials, for the deposited materials. For example, the PCM material may be nitrogen doped up to about 10 atomic %, such as from about 2 to about 5 atomic %, by which a dopant gas, such as nitrogen gas, is selectively supplied during plasma sputtering of the target. A dopant gas may be introduced into the chamber at a flow rate from about 0.05 sccm to about 40 sccm, such as from about 0.1 sccm to about 20 sccm, for example, about 2 sccm.

The sputtering process may be performed by maintaining a chamber pressure of about 5 milliTorr or greater, such as from about 6 milliTorr to about 100 milliTorr, for example, about 26 milliTorr. The sputtering process may be performed by maintaining a substrate temperature from about 25° C. to about 350° C., such as at a temperature from about 25° C. to about 300° C., for example, about 30° C. or about 200° C. The substrate and target may be spaced from about 50 mm to about 500 mm, such as from about 100 mm to about 400 mm, for example, about 290 mm, apart.

An example of the deposition process comprises utilizing a target of Ge₂Sb₂Te₅ material, introducing an argon processing gas at a flow rate of about 80 sccm, applying a DC/RF power level of about 2500 W to the target, applying a RF power level of about 400 to an electrostatic chuck, maintaining a chamber pressure of about 40 MilliTorr, maintaining a chamber temperature of about 30° C. or about 200° C., at a target to substrate spacing of about 90 mm.

While the foregoing is directed to embodiments of the present invention, other and further embodiments of the invention may be devised without departing from the basic scope thereof, and the scope thereof is determined by the claims that follow.

What is claimed is:

1. A method for processing a substrate, comprising:
positioning a substrate in a processing chamber having a chalcogenide-based target coupled to a first power source, and one or more coils coupled to a second power source;
providing a processing gas to the processing chamber;
applying RF power to the target at a frequency of about 13.56 MHz and applying power to the one or more coils to generate an inductively coupled plasma;
sputtering material from the target;
ionizing the sputtered material; and
depositing the sputtered material onto a surface of the substrate.

2. The method of claim 1, wherein the chalcogenide-based target comprises two or more elements from Groups 11-16 of the IUPAC Periodic Table.

3. The method of claim 2, wherein the elements of the chalcogenide-based target are selected from the group consisting of AgSe, GeSb, GeSe, GeTe, SbTe, GeSbTe, GeSeTe, AgInSbTe, GeSbSeTe, TeGeSbS, and combinations thereof.

4. The method of claim 2, wherein the chalcogenide-based target is further doped with nitrogen, oxygen, bismuth, tin, indium, silicon, or combinations thereof.

5. The method of claim 1, wherein the coils comprise a material selected from the group consisting of titanium, tantalum, copper, aluminum, phase change-based materials, phase change-based material dopants, and combinations thereof.

6. The method of claim 1, further comprising applying a second frequency of about 60 MHz to the target, the coil, or both.

7. The method of claim 1, wherein the coils comprise from 2 to 5 coils.

8. The method of claim 16, wherein the RF power applied to the target is between about 50 W and about 5000 W.

9. A method for processing a substrate, comprising:
positioning a substrate in a processing chamber having a chalcogenide-based target coupled to a first power source, and a substrate support coupled to a second power source;
providing a processing gas to the processing chamber;
biasing the target with continuous DC, pulsed DC power, or RF power;
applying a single or dual frequency RF power to the substrate support;
sputtering material from the target;
ionizing the sputtered materials; and
depositing the sputtered materials on the substrate surface.

10. The method of claim 9, wherein the biasing the target comprises biasing the target at 10 kHz to about 300 kHz and modulating the bias at a frequency of less than about 10 kHz.

11. The method of claim 9, wherein the dual frequency RF power comprise 13.56 MHz and 60 MHz frequencies.

12. The method of claim 9, wherein the dual frequency RF power comprise 13.56 MHz and 2 MHz frequencies.

13. The method of claim 9, wherein the substrate support comprises an electrostatic chuck.

14. The method of claim 9, wherein the chalcogenide-based target comprise two or more elements from Groups 9-16 of the IUPAC Periodic Table.

15. The method of claim 16, wherein the elements of the chalcogenide-based target selected from the group consisting of AgSe, GeSb, GeSe, GeTe,

16. The method of claim 14, wherein the chalcogenide-based target is further doped with nitrogen, oxygen, bismuth, tin, indium, silicon, or combinations thereof.
